(19) United States
(12) Patent Application Publication
(10) Pub. No.: US 2024/0413126 A1
(43) Pub. Date: Dec. 12, 2024

(54) SEMICONDUCTOR DEVICE AND MANUFACTURING METHOD OF SEMICONDUCTOR DEVICE

(71) Applicant: LAPIS Semiconductor Co., Ltd., Yokohama-shi (JP)

(72) Inventor: Kentarou ARAI, Yokohama-shi (JP)

(73) Assignee: LAPIS Semiconductor Co., Ltd., Yokohama-shi (JP)

(21) Appl. No.: 18/814,349

(22) Filed: Aug. 23, 2024

Related U.S. Application Data
(63) Continuation of application No. PCT/JP2023/007372, filed on Feb. 28, 2023.

(30) Foreign Application Priority Data
Feb. 28, 2022 (JP) 2022-029035

(51) Int. Cl. H01L 25/065; H01L 23/00; H01L 25/00

(52) U.S. Cl. CPC H01L 25/0657; H01L 24/08; H01L 24/80; H01L 24/94; H01L 25/50; H01L 2224/08145; H01L 2224/80895; H01L 2224/80896; H01L 2225/06548

(57) ABSTRACT

A semiconductor device includes a first semiconductor chip, a second semiconductor chip, a post electrode, and a burying layer. The first semiconductor chip includes a plurality of first metal terminals and external metal terminals formed in different regions, and a bonding layer including an oxide film to fill therebetween. The second semiconductor chip includes a plurality of second metal terminals formed on an opposed surface of the first semiconductor chip and a bonding layer including an oxide film provided to fill therebetween. The second semiconductor chip is mounted on the first semiconductor chip by bonding the bonding layers one another. The post electrode is formed above the one surface of the first semiconductor chip and provided on the external metal terminal of the first semiconductor chip. The burying layer buries the second semiconductor chip and the post electrode on the one surface of the first semiconductor chip.

### TECHNICAL FIELD

The present disclosure relates to a semiconductor device, in particular, a semiconductor device having a structure in which a core chip is mounted on a base chip, and a manufacturing method thereof.

### BACKGROUND ART

Wafer level Chip Size Package (WL-CSP) is used as a package for LSI chips in which rewiring, electrode formation, resin encapsulation, and dicing are performed in wafer process. In the WL-CSP, circuit elements formed on the main surface of a semiconductor substrate are connected to external elements by rewiring (for example, Patent Document 1).
Patent Document 1: Japanese Unexamined Patent Application Publication No. 2019-62065

In the case of the semiconductor devices with a WL-CSP structure, when a plurality of chips are stacked to form a single package, the upper and lower chips are connected to one another using wire bonding or through electrodes.

However, when the wire bonding or the through electrode is used, the chip size increases by that amount, making it difficult to downsize the package.

The present disclosure has been made in view of the above-mentioned problems and an object of which is to achieve a downsizing of a chip size with a simple structure in a semiconductor devices with a WL-CSP structure.

### SUMMARY

A semiconductor device according to the present disclosure includes a first semiconductor chip, a second semiconductor chip, a post electrode, and a burying layer. The first semiconductor chip includes a plurality of first metal terminals, a plurality of external metal terminals, and a bonding layer. The plurality of first metal terminals are formed in one region of one surface. The plurality of external metal terminals are formed in another region of the one surface. The bonding layer includes an oxide film provided on the one surface to fill between the plurality of first metal terminals and the plurality of external metal terminals. The second semiconductor chip includes a plurality of second metal terminals and a bonding layer. The plurality of second metal terminals are formed on an opposed surface opposed to the one surface of the first semiconductor chip, the bonding layer including an oxide film provided on the opposed surface to fill between the plurality of second metal terminals. The second semiconductor chip is mounted on the first semiconductor chip by bonding the bonding layers one another such that the respective plurality of second metal terminals contact the respective plurality of first metal terminals formed on the first semiconductor chip. The post electrode is formed above the one surface of the first semiconductor chip and provided on the external metal terminal of the first semiconductor chip through a metal film. The burying layer buries the second semiconductor chip and the post electrode on the one surface of the first semiconductor chip.

A manufacturing method of a semiconductor device according to the present disclosure includes: a first step of mounting a second semiconductor chip on a first semiconductor chip, the first semiconductor chip including a plurality of first metal terminals, a plurality of external metal terminals, and a bonding layer, the plurality of first metal terminals being formed in one region of one surface, the plurality of external metal terminals being formed in another region of the one surface, the bonding layer including an oxide film provided on the one surface to fill between the plurality of first metal terminals and the plurality of external metal terminals, the second semiconductor chip having one surface on which a plurality of second metal terminals and a bonding layer are formed, the bonding layer including an oxide film to fill between the plurality of second metal terminals, the second semiconductor chip being mounted on the first semiconductor chip by bonding the bonding layers one another such that the respective plurality of second metal terminals contact the respective plurality of first metal terminals formed on the first semiconductor chip; a second step of processing a side surface of the second semiconductor chip after the first step; a third step of forming a metal film covering the one surface of the first semiconductor chip and a surface of the second semiconductor chip excluding an opposed surface opposed to the one surface of the first semiconductor chip; a fourth step of forming a resist film with an opening on the metal film; a fifth step of forming a post electrode on the external metal terminal of the first semiconductor chip through the metal film in a region corresponding to the opening of the resist film; and a sixth step of removing the metal film and the resist film to form a burying layer burying the second semiconductor chip and the post electrode on the one surface of the first semiconductor chip.

### BRIEF DESCRIPTION OF THE DRAWINGS

FIG. 1 is a top view of a semiconductor device.

FIG. 2 is a cross-sectional view along the 2-2 line of the semiconductor device of FIG. 1.

FIG. 3 is a flowchart illustrating of a manufacturing step of the semiconductor device.

FIG. 4A is a cross-sectional view of a semiconductor device in a core chip mounting step.

FIG. 4B is a cross-sectional view of a semiconductor device in a core chip thinning step.

FIG. 4C is a cross-sectional view of a semiconductor device in a core chip side surface processing step.

FIG. 4D is a cross-sectional view of a semiconductor device in a UBM film formation step.

FIG. 5A is a cross-sectional view of a semiconductor device in a resist formation step.

FIG. 5B is a cross-sectional view of a semiconductor device in a resist exposure/development step.

FIG. 5C is a cross-sectional view of a semiconductor device in a Cu post formation step.

FIG. 6A is a cross-sectional view of a semiconductor device in a resist removal step.

FIG. 6B is a cross-sectional view of a semiconductor device in a UBM film removal step.

FIG. 6C is a cross-sectional view of a semiconductor device in a mold forming step.

FIG. 7A is a cross-sectional view of a semiconductor device in a mold grinding step.

FIG. 7B is a cross-sectional view of a semiconductor device in a solder terminal formation step.

FIG. 7C is a cross-sectional view of a semiconductor device in a dicing step.

### DETAILED DESCRIPTION

The following describes preferred embodiments of the present disclosure in detail. In the description and attached drawings of each embodiment below, same reference numerals are given to substantially same or equivalent parts.

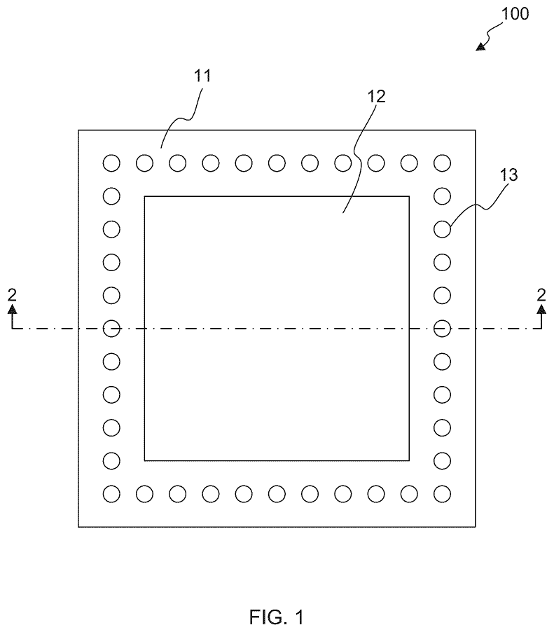

FIG. 1 is a top view of a semiconductor device 100 according to an embodiment of the present disclosure, viewed from above a device formation surface (one surface).

The semiconductor device 100 has a structure in which a core chip 12 is mounted on a base chip 11. A plurality of Cu posts (omitted in FIG. 1), which form a part of a wiring pattern, are formed around the core chip. A solder terminal 13 is formed on a top surface of each of the plurality of Cu posts, and the solder terminals 13 are arranged to surround a periphery of the core chip 12 in the top view as illustrated in FIG. 1.

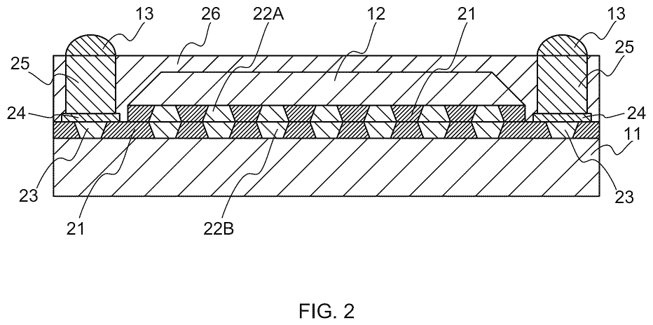

FIG. 2 is a cross-sectional view along the 2-2 line of FIG. 1. The semiconductor device 100 includes the base chip 11, the core chip 12, UBMs 24, Cu posts 25, and a mold 26. On one surface of the base chip 11, which is a device mounting surface (hereinafter referred to as the top surface), a plurality of Cu connection terminals 22B, a plurality of external connection terminals 23, and an oxide film 21 formed to fill therebetween are formed. On one surface of the core chip 12, which is an opposed surface opposed to the top surface of the base chip 11 (hereinafter referred to as a bottom surface), a plurality of Cu connection terminals 22A and an oxide film 21 formed to fill therebetween are formed.

The oxide film 21 is constituted of, for example, SiO2. The oxide film 21 formed on the base chip 11 forms a bonding layer together with the Cu connection terminals 22B in a region where the Cu connection terminals 22B are formed. Similarly, the oxide film 21 formed on the core chip 12 forms a bonding layer together with the Cu connection terminals 22A in a region where the Cu connection terminals 22A are formed.

For the top surface of the base chip 11 and the bottom surface of the core chip 12, the respective bonding layers are bonded to one another such that the Cu connection terminals 22A and the Cu connection terminals 22B are in contact with one another. This creates Cu-Cu connections, directly connecting the base chip 11 to the core chip 12.

The external connection terminal 23 is provided in a region where the Cu post 25 is formed on the top surface of the base chip 11. The region is formed in a location adjacent to a region where the Cu connection terminal 22B is formed.

A UBM 24 is an Under Barrier Metal (UBM) film provided to form the Cu post 25, and is constituted of a metal film composed of a Ti layer and a Cu layer, for example. The UBMs 24 are formed on the external connection terminal 23 on the top surface of the base chip 11.

The Cu post 25 is a columnar post electrode constituted of Cu. The Cu post 25 is formed on the top surface of the base chip 11 and is connected to the base chip 11 through the UBM 24 and the external connection terminal 23. The solder terminal 13 is formed on a top of the Cu post 25 (that is, on an opposite side of the base chip 11).

The mold 26 is a sealing layer constituted of, for example, a thermosetting epoxy resin. The mold 26 is formed on the top surface of the base chip 11 so as to bury the core chip 12 and the Cu posts 25.

The core chip 12 has a shape of a frustum whose top surface (that is, the side opposite to the bottom surface) is smaller than the bottom surface. In other words, the core chip 12 includes side surface portions that are sloped (tapered shape) and have a shape that tapers from the bottom surface toward the top surface.

After the core chip 12 is mounted on the base chip 11, a side surface processing by dicing is performed to form the slopes. The side surface processing by dicing may be followed by further a side surface processing by etching. This sloping of the side surface portions enables the side surface portions of the core chip 12 to be sufficiently coated during a UBM film formation processing and a photolithography processing to form the Cu posts 25 in the following manufacturing steps.

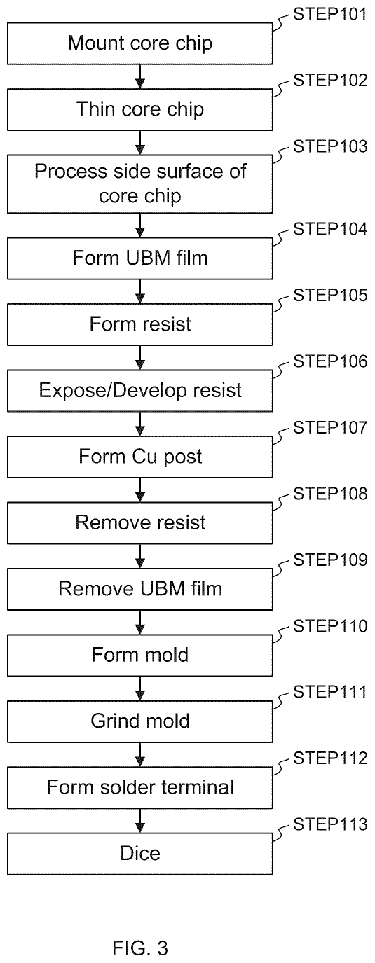

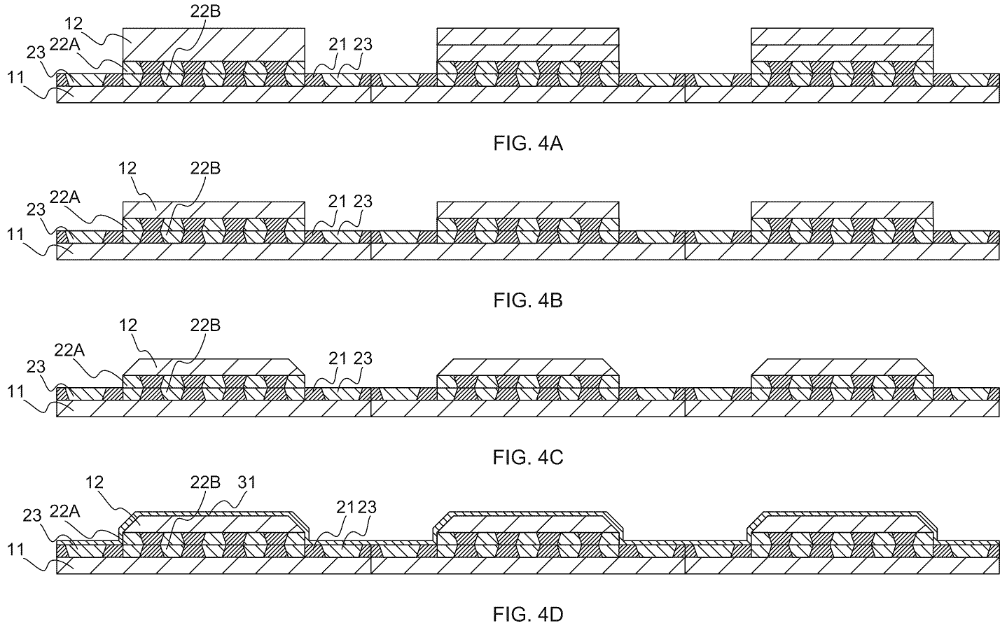

Next, a manufacturing method of the semiconductor device 100 of the embodiment will be described. FIG. 3 illustrates a flowchart of the manufacturing method. FIGS. 4A to 4D, 5A to 5C, 6A to 6C, and 7A to 7C are cross-sectional views of a wafer at each step of the flowchart in FIG. 3.

First, as illustrated in FIG. 4A, a core chip mounting processing is performed to mount the core chip 12 on the top surface of the base chip 11 (STEP 101). Specifically, a base chip 11 with an oxide film 21 and Cu connection terminals 22A formed on the top surface thereof and a core chip 12 with an oxide film 21 and Cu connection terminals 22B formed thereon are prepared, and the core chip 12 is mounted on the base chip 11 such that positions of the Cu connection terminals 22B on the base chip 11 side overlap positions of the Cu connection terminals 22A on the core chip 12 side.

Next, a core chip thinning processing is performed on the wafer illustrated in FIG. 4A (STEP 102). Specifically, a thinning processing by grinding is performed on the core chip 12 mounted on the base chip 11. This reduces a thickness of the core chip 12 as illustrated in FIG. 4B. In the embodiment, the core chip 12 having a thickness of about 725 μm is thinned to a thickness of about 100 μm, for example.

Next, a side surface processing of the core chip is performed on the wafer illustrated in FIG. 4B (STEP 103). Specifically, the side surface portions of the core chip 12 are processed by dicing and etching. This creates slopes on the side surface portions of the core chip 12 as illustrated in FIG. 4C.

Next, a UBM film formation processing is performed on the wafer illustrated in FIG. 4C (STEP 104). Specifically, an Under Barrier Metal (UBM) film 31 is formed to cover the oxide film 21 and the Cu connection terminals 22B exposed on a wafer surface and a surface including the top surface and side surface portions of the core chip 12. The UBM film 31 is formed, for example, by forming a layered film of Ti to be an adhesion layer and Cu to be a seed layer by sputtering. As a result, the UBM film 31 is formed to cover the entire surface of the wafer as illustrated in FIG. 4D.

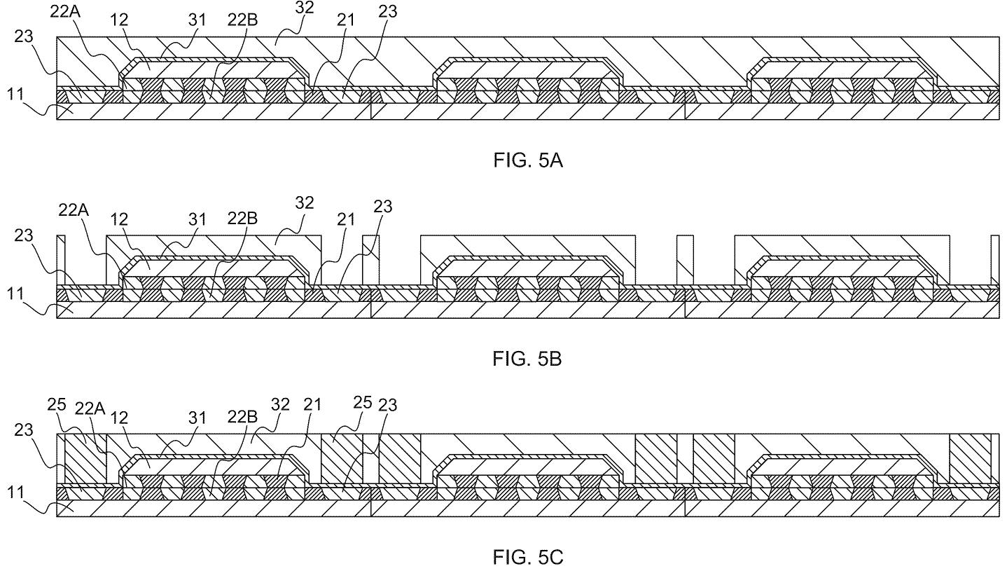

Next, a resist formation processing is performed on the wafer illustrated in FIG. 4D (STEP 105). Specifically, a resist film 32 is formed to further cover the surface of the UBM film 31. As a result, the resist film 32 is formed to cover the entire surface of the wafer as illustrated in FIG. 5A.

Next, a resist exposure/developing processing is performed on the wafer illustrated in FIG. 5A (STEP 106). Specifically, after patterning to form the Cu posts 25 on the resist film 32 formed in STEP 105, exposure and development are performed. As illustrated in FIG. 5B, this forms a resist mask in which the resist films at the positions where the Cu posts 25 are formed are removed.

Next, a Cu post formation processing is performed on the wafer illustrated in FIG. 5B (STEP 107). Specifically, Cu is stacked by plating processing using the resist mask formed in STEP 106. This creates the Cu posts 25 at the locations of apertures of the resist mask as illustrated in FIG. 5C.

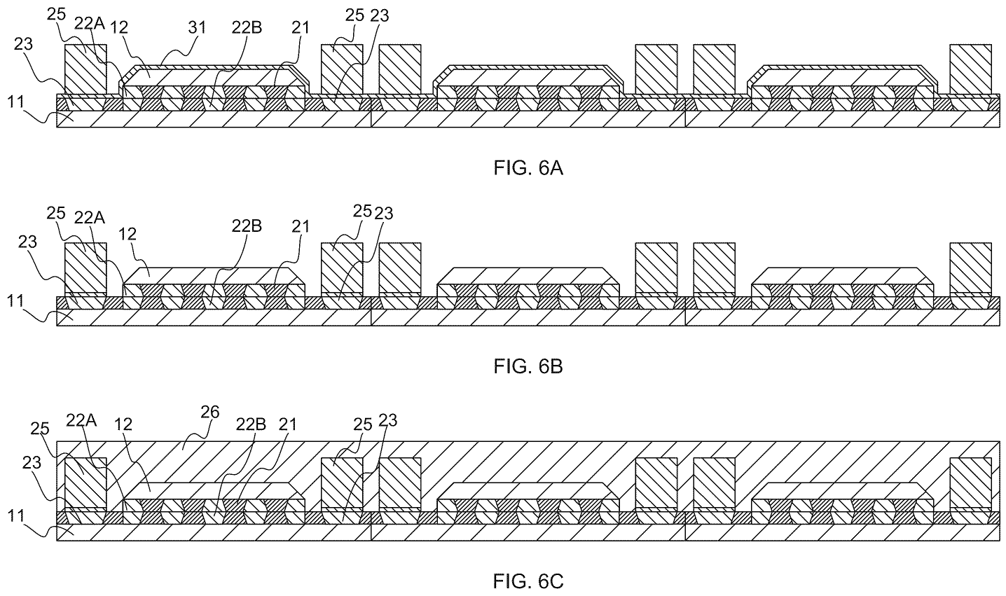

Next, a resist removal processing is performed on the wafer illustrated in FIG. 5C (STEP 108). Specifically, the resist is removed by ashing with an ashing device, immersion in an organic stripping solution, or the like. This removes the resist film 32 formed on the wafer top surface as illustrated in FIG. 6A.

Next, a UBM film removal processing is performed on the wafer illustrated in FIG. 6A (STEP 109). Specifically, a wet etching is used to remove the Cu layer and the Ti layer that constitute the UBM film 31. This removes the UBM film 31 formed on the wafer top surface as illustrated in FIG. 6B.

Next, a mold formation processing is performed on the wafer illustrated in FIG. 6B (STEP 110). Specifically, exposed surfaces of the core chip 12 and the Cu posts 25 are coated with a mold resin. The entire wafer surface is then covered with a mold 26 as illustrated in FIG. 6C.

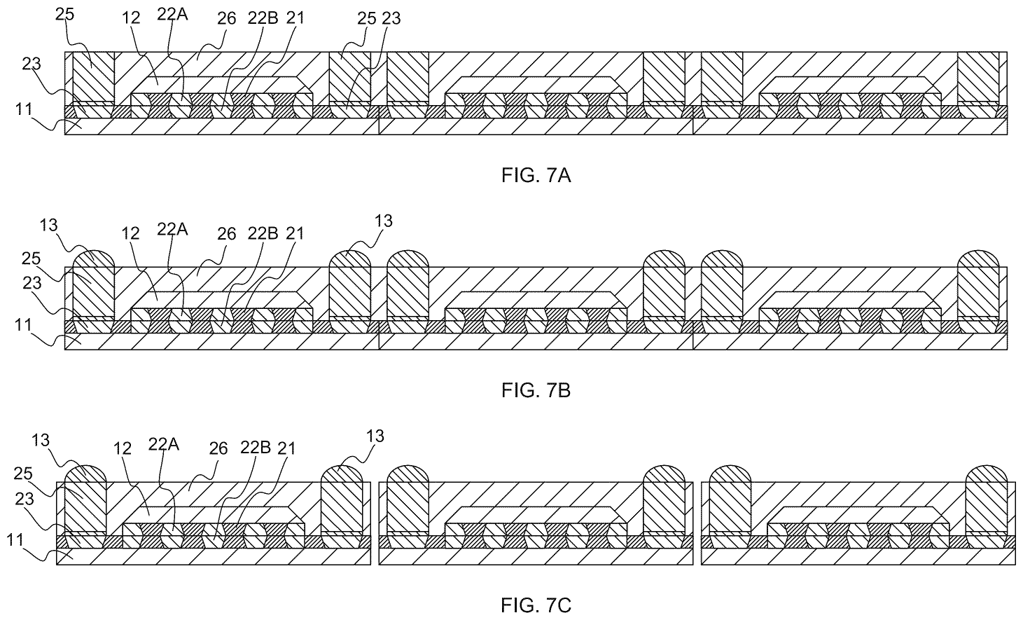

Next, a mold grind processing is performed on the wafer illustrated in FIG. 6C (STEP 111). Specifically, the mold layer is ground up to a position to expose the top surface of the Cu posts 25. This removes the mold 26 in a portion exceeding the heights of the Cu posts 25 as illustrated in FIG. 7A.

Next, a solder terminal formation processing is performed on the wafer illustrated in FIG. 7A (STEP 112). Specifically, solder terminals are formed on the top surfaces of the Cu posts 25, that is, the surfaces exposed from the mold 26 by solder printing or ball mounting. This forms a wafer with the solder terminals 13 as illustrated in FIG. 7B.

Next, a dicing processing is performed on the wafer illustrated in FIG. 7B (STEP 113). Specifically, the wafer is diced into individual chips using a dicer. This forms the semiconductor devices illustrated in FIG. 7C.

The semiconductor devices 100 are manufactured through the steps described above.

In the semiconductor device 100 of the embodiment, the core chip 12 is mounted on the base chip 11 such that the Cu connection terminals 22B formed on the surface of the base chip 11 are directly connected to the Cu connection terminals 22A formed on the surface of the core chip 12. Thus, by using the Cu-Cu connections to connect the chip, it is possible to achieve the chip size reduction with a simple structure in a semiconductor device with a WL-CSP structure.

In the semiconductor device 100 of the embodiment, after mounting the core chip 12 on the base chip 11, a side surface processing of the core chip 12 is performed to form a slope in a tapered shape with a predetermined angle. By forming such a slope, the entire surface of the core chip 12 (more specifically, the surface other than the surface to be bonded to the base chip 11) can be adequately covered in the subsequent processing of the forming of the UBM film and the forming of the resist.

If the UBM film and the resist were formed with a core chip having a vertical edge shape mounted, unlike the embodiment, the side surface portion of the core chip would not be coated, making it difficult to form a wiring pattern.

With the semiconductor device 100 of the embodiment, the formation and the photolithography processing of the UBM film on the surface of the core chip can be easily performed by providing the slope in the tapered shape on the side surface portion of the core chip.

In addition, it is generally difficult to mount a thin core chip on a base chip. However, in the manufacturing method of the semiconductor device 100 of the embodiment, a core chip 12 with a certain thickness can be mounted on the base chip 11 because the thinning and the side surface processing of the core chip 12 are performed after the core chip 12 is mounted on the base chip 11.

The disclosure is not limited to those illustrated in the above-described embodiment. For example, the above-described embodiment describes a case in which the metal connection terminal provided on the base chip 11 is the Cu connection terminal 22B. However, the connection terminal is not limited to the Cu connection terminal, but may be an Al connection terminal made of Al (aluminum), for example.

DESCRIPTION OF REFERENCE SIGNS

| | |
|---|---|
| 100 | Semiconductor device |
| 11 | Base chip |
| 12 | Core chip |
| 13 | Solder terminal |
| 21 | Oxide film |
| 22A, 22B | Cu connection terminal |
| 24 | UBM |
| 25 | Cu post |
| 26 | Mold |
| 31 | UBM film |
| 32 | Resist film |

1. A semiconductor device comprising:
a first semiconductor chip including a plurality of first metal terminals, a plurality of external metal terminals, and a bonding layer, the plurality of first metal terminals being formed in one region of one surface, the plurality of external metal terminals being formed in another region of the one surface, the bonding layer including an oxide film provided on the one surface to fill between the plurality of first metal terminals and the plurality of external metal terminals;
a second semiconductor chip including a plurality of second metal terminals and a bonding layer, the plurality of second metal terminals being formed on an opposed surface opposed to the one surface of the first semiconductor chip, the bonding layer including an oxide film provided on the opposed surface to fill between the plurality of second metal terminals, the second semiconductor chip being mounted on the first semiconductor chip by bonding the bonding layers one another such that the respective plurality of second metal terminals contact the respective plurality of first metal terminals formed on the first semiconductor chip;
a post electrode formed above the one surface of the first semiconductor chip and provided on the external metal terminal of the first semiconductor chip through a metal film; and
a burying layer burying the second semiconductor chip and the post electrode on the one surface of the first semiconductor chip.

2. The semiconductor device according to claim 1, wherein
the second semiconductor chip has a side surface portion that is sloped.

3. The semiconductor device according to claim 2, wherein
the second semiconductor chip has a shape that tapers upward from the opposed surface.

4. The semiconductor device according to claim 1, wherein
the plurality of first metal terminals are constituted of Cu or Al, and
the plurality of second metal terminals are constituted of Cu.

5. The semiconductor device according to claim 1, wherein
the plurality of first metal terminals and the plurality of second metal terminals are constituted of Cu.

6. The semiconductor device according to claim 1, wherein
the post electrode has a solder terminal formed on the top surface.

7. A manufacturing method of a semiconductor device, comprising:
a first step of mounting a second semiconductor chip on a first semiconductor chip, the first semiconductor chip including a plurality of first metal terminals, a plurality of external metal terminals, and a bonding layer, the plurality of first metal terminals being formed in one region of one surface, the plurality of external metal terminals being formed in another region of the one surface, the bonding layer including an oxide film provided on the one surface to fill between the plurality of first metal terminals and the plurality of external metal terminals, the second semiconductor chip having one surface on which a plurality of second metal terminals and a bonding layer are formed, the bonding layer including an oxide film to fill between the plurality of second metal terminals, the second semiconductor chip being mounted on the first semiconductor chip by bonding the bonding layers one another such that the respective plurality of second metal terminals contact the respective plurality of first metal terminals formed on the first semiconductor chip;
a second step of processing a side surface of the second semiconductor chip after the first step;
a third step of forming a metal film covering the one surface of the first semiconductor chip and a surface of the second semiconductor chip excluding an opposed surface opposed to the one surface of the first semiconductor chip;
a fourth step of forming a resist film with an opening on the metal film;
a fifth step of forming a post electrode on the external metal terminal of the first semiconductor chip through the metal film in a region corresponding to the opening of the resist film; and
a sixth step of removing the metal film and the resist film to form a burying layer burying the second semiconductor chip and the post electrode on the one surface of the first semiconductor chip.

8. The manufacturing method of a semiconductor device according to claim 7, wherein
the second step includes forming a slope in a side surface portion of the second semiconductor chip by dicing such that the second semiconductor chip has a shape that tapers upward from the opposed surface.

9. The manufacturing method of a semiconductor device according to claim 8, wherein
the second step further includes forming a slope in the side surface portion of the second semiconductor chip by performing etching after the dicing.

10. The manufacturing method of a semiconductor device according to claim 7, wherein
the plurality of first metal terminals are constituted of Cu or Al, and
the plurality of second metal terminals are constituted of Cu.

11. The manufacturing method of a semiconductor device according to claim 7, further comprising:
a seventh step of forming a solder terminal on the top surface of the post electrode.
